(19) United States
(12) Patent Application Publication
(10) Pub. No.: US 2016/0291365 A1
(43) Pub. Date: Oct. 6, 2016

(54) LIQUID CRYSTAL DISPLAY AND METHOD FOR MANUFACTURING THE SAME

(71) Applicant: Samsung Display Co., Ltd., Yongin-si (KR)

(72) Inventors: Seong Gyu KWON, Suwon-si (KR); Jae Cheol PARK, Hwaseong-si (KR); Dae Ho SONG, Hwaseong-si (KR); You Young JIN, Suwon-si (KR)

(21) Appl. No.: 15/060,315

(22) Filed: Mar. 3, 2016

(30) Foreign Application Priority Data
Mar. 31, 2015 (KR) 10-2015-0045219

(51) Int. Cl. G02F 1/1341; H01L 27/12; G02F 1/1335; G02F 1/1368; G02F 1/1333

(52) U.S. Cl. CPC G02F 1/1341; G02F 1/1368; G02F 1/133377; G02F 1/133512; H01L 27/1259

(57) ABSTRACT

A liquid crystal display including: a substrate including a display area and a peripheral area, a plurality of thin film transistors disposed on the substrate in the display area, a plurality of pixel electrodes disposed on the plurality of thin film transistors and connected to the plurality of thin film transistor, respectively, a plurality of roof layers disposed on the plurality of pixel electrodes so as to face the plurality of pixel electrodes, a plurality of liquid crystal layers disposed in a plurality of micro cavities formed between the plurality of pixel electrodes and the roof layer, and a capping layer covering liquid crystal inlets formed between the plurality of micro cavities and including a light blocking material suitable for inkjet processing, wherein the plurality of roof layers includes protrusion parts or concave parts disposed at one side of the plurality of roof layers adjacent to the capping layer.

### CROSS-REFERENCE TO RELATED APPLICATION

This application claims priority to and the benefit of Korean Patent Application No. 10-2015-0045219 filed in the Korean Intellectual Property Office on Mar. 31, 2015, the entire contents of which are incorporated herein by reference.

### BACKGROUND

(a) Field

The present inventive concept relates to a liquid crystal display and a method for manufacturing the same.

(b) Description of the Related Art

A liquid crystal display, which is one of flat panel displays that are currently used widely, includes two display panels on which electric field generating electrodes such as pixel electrodes, common electrodes, and the like, are formed, and a liquid crystal layer interposed between the two display panels.

A voltage is applied to the electric field generating electrodes to generate an electric field in the liquid crystal layer, thereby determining alignment of liquid crystal molecules of the liquid crystal layer and controlling polarization of incident light to display an image.

As one of the liquid crystal displays, a technology of implementing a display by forming a plurality of micro cavities in pixels and filling the micro cavities with liquid crystals has been developed. In a liquid crystal display according to the related art, two substrates have been used. In this technology, components may be formed on one substrate to decrease a weight, a thickness, and the like, of the liquid crystal display.

In a process of filling the micro cavities with liquid crystal to form a display, the liquid crystal may be injected through liquid crystal inlets, the liquid crystal inlets may be closed after the liquid crystal is injected, and an encapsulation process may be performed in order to protect an entire element.

The above information disclosed in this Background section is only for enhancement of understanding of the background of the inventive concept and therefore it may contain information that does not form the prior art.

### SUMMARY

The present inventive concept has been made in an effort to provide a liquid crystal display and a method for manufacturing the same having advantages of including a capping layer made of a material on which an inkjet process may be performed.

The present inventive concept has also been made in an effort to provide a liquid crystal display and a method for manufacturing the same having advantages of including a capping layer made of a material that may block light.

The present inventive concept has also been made in an effort to provide a liquid crystal display and a method for manufacturing the same having advantages of including a capping layer blocking a liquid crystal inlet without polluting liquid crystal.

An exemplary embodiment of the present inventive concept provides a liquid crystal display including: a substrate including a display area and a peripheral area; a plurality of thin film transistors disposed on the substrate in the display area; a plurality of pixel electrodes disposed on the plurality of thin film transistors and connected to the plurality of thin film transistor, respectively; a plurality of roof layers disposed on the plurality of pixel electrodes so as to face the plurality of pixel electrodes; a plurality of liquid crystal layers disposed in a plurality of micro cavities formed between the plurality of pixel electrodes and the roof layer; and a capping layer covering liquid crystal inlets formed between the plurality of micro cavities and including a light blocking material suitable for inkjet processing, wherein the plurality of roof layers includes protrusion parts or concave parts disposed at one side of the plurality of roof layers adjacent to the capping layer. The capping layer may be disposed along the liquid crystal inlets.

Each of the protrusion parts may have a convex portion in which the convex portion protrudes upwardly higher than the capping layer.

The capping layer may include a first light blocking member disposed along the liquid crystal inlets and a second light blocking member disposed along data lines and intersecting with the first light blocking member, and the first light blocking member and the second light blocking member may include the same material.

The protrusion parts may be formed at sides of the plurality of roof layers adjacent to the first light blocking member and the second light blocking member, and have a convex portion in which the convex portion protrudes upwardly higher than the first light blocking member and the second light blocking member.

The concave parts may have a form in which the concave parts are relatively further recessed concavely as compared with the roof layer.

The capping layer may have hydrophobicity, and a surface of the roof layer may have hydrophobicity.

The liquid crystal display may further include a plurality of dummy dams formed in the peripheral area and enclosing the display area, the dummy dams protruding upwardly higher than the capping layer.

The liquid crystal display may further include a plurality of dummy dams formed in at an outer side of the peripheral area and enclosing the peripheral area.

The plurality of dummy dams may have a stripe shape or a dot shape.

The light blocking material suitable for inkjet processing may include a water soluble black dye or a black pigment.

The water soluble black dye may include at least one of 2-naphthalenesulfonic acid, trisodium 6-[(7-amino-1-hydroxy-3-sulphonato-2-naphthyl)azo]-3-[[4-[[4-amino-6 (or 7)-sulphonatonaphthyl]azo]phenyl]azo]-4-hydroxynaphthalene-2-sulphonate, trisodium 4-amino-3-[[4-[[4-[(2-amino-4-hydroxyphenyl)azo]phenyl]amino]-3-sulphonato phenyl]azo]-5-hydroxy-6-(phenylazo)naphthalene-2, 7-disulphonate, and disodium 4-amino-3, 6-bis[[4-[(2, 4-diaminophenyl) azo]phenyl]azo]-5-hydroxynaphthalene-2, 7-disulphonate 2, 7-naphthalenedisulfonic acid.

Another exemplary embodiment of the present inventive concept provides a method for manufacturing a liquid crystal display including: forming a plurality of thin film transistors on a substrate including a display area and a peripheral area; forming a plurality of pixel electrodes on the plurality of thin film transistors in the display area; forming a plurality of sacrificial layers on the plurality of pixel electrodes; forming a plurality of roof layers on the plurality of sacrificial layers, the plurality of roof layers including protrusion parts; forming micro cavities between which liquid crystal inlets are formed by removing the sacrificial layer; injecting a liquid crystal material into the micro cavities through the liquid crystal inlets; and forming a capping layer in the display area and the peripheral area using an inkjet processing so as to cover the liquid crystal inlets.

The capping layer may be disposed along the liquid crystal inlets.

The protrusion parts may be formed at one side of the roof layers adjacent to the liquid crystal inlets, the protrusion part protruding upwardly higher than the capping layer.

The roof layer and the protrusion parts may be made of the same material.

The capping layer may include a light blocking material suitable for inkjet processing.

The light blocking material suitable for inkjet processing includes a water soluble black dye or a black pigment.

Other features and advantages of the present inventive concept, in addition to the technical object of the present inventive concept described above, will be described below or will be clearly understood by those skilled in the art to which the present inventive concept pertains from the following description.

The present inventive concept as described above has the following effects.

In the present inventive concept, the capping layer is formed in the inkjet scheme, thereby making it possible to simplify a process as compared with the case in which the capping layer is formed by the photo process, the capping layer including the light blocking material is formed, thereby making it possible to omit a process of separately forming a light blocking member, and the capping layer including the water soluble polymer material is formed, thereby making it possible to prevent pollution of the liquid crystal.

### BRIEF DESCRIPTION OF THE DRAWINGS

FIG. 1 is a plan view showing portions of a peripheral area and a display area in a liquid crystal display according to an exemplary embodiment of the present inventive concept.

FIG. 2 is a plan view showing the liquid crystal display according to an exemplary embodiment of the present inventive concept.

FIG. 3 is a cross-sectional view taken along line of FIG. 2.

FIG. 4 is a cross-sectional view taken along line IV-IV of FIG. 2.

FIG. 5 is a plan view showing a color filter and a partition wall part in the liquid crystal display according to an exemplary embodiment of the present inventive concept.

FIG. 6 is a cross-sectional view taken along line VI-VI of FIG. 5.

FIG. 7 is a plan view showing a layout of a capping layer and a protrusion part in the liquid crystal display according to an exemplary embodiment of the present inventive concept.

FIG. 8 is a cross-sectional view showing a liquid crystal display modified from an exemplary embodiment of FIG. 4.

FIG. 9 is a plan view showing a layout of a capping layer and a protrusion part in the liquid crystal display according to an exemplary embodiment of the present inventive concept of FIG. 8.

FIG. 10 is a cross-sectional view showing a liquid crystal display modified from an exemplary embodiment of FIG. 4.

FIG. 11 is a cross-sectional view showing a liquid crystal display modified from an exemplary embodiment of FIG. 3.

FIGS. 12, 13 and 14 are views showing a liquid crystal display according to another exemplary embodiment of the present inventive concept.

FIG. 15 is a flow chart showing a method for manufacturing a liquid crystal display according to an exemplary embodiment of the present inventive concept.

### DETAILED DESCRIPTION OF THE EMBODIMENTS

Exemplary embodiments of the present inventive concept will be described in detail with reference to the accompanying drawings. However, the present inventive concept is not limited to exemplary embodiments described therein, but may also be embodied in other forms. On the contrary, exemplary embodiments introduced herein are provided to make disclosed contents thorough and complete and sufficiently transfer the spirit of the present inventive concept to those skilled in the art.

In the accompanying drawings, thickness of layers and regions may be exaggerated for clarity. In addition, it will be understood that when a layer is referred to as being “on” another layer or substrate, the layer can be directly disposed on another layer or substrate or the other layer may also be interposed therebetween. Like reference numerals designate like elements throughout the specification.

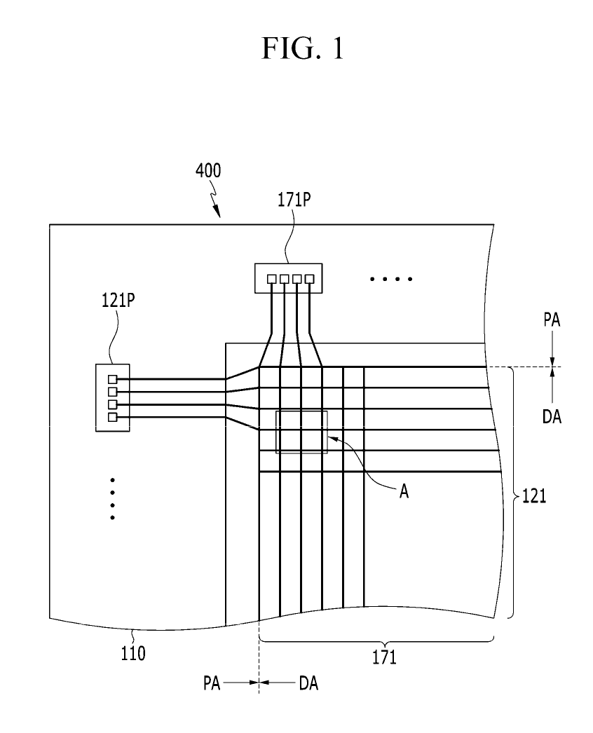

FIG. 1 is a plan view showing portions of a peripheral area and a display area in a liquid crystal display according to an exemplary embodiment of the present inventive concept.

Referring to FIG. 1, the liquid crystal display according to an exemplary embodiment of the present inventive concept may include a liquid crystal panel assembly 400 and a gate driver (not shown) and a data driver (not shown) connected to the liquid crystal panel assembly 400, a gray voltage generator (not shown) connected to the data driver, a light source unit (not shown) irradiating light to the liquid crystal panel assembly 400, a light source driver (not shown) controlling the light source unit, and a signal controller (not shown) controlling these components.

The gate driver or the data driver may be formed on the liquid crystal panel assembly 400 or be formed as separate integrated circuit (IC) chips.

A substrate 110 of the liquid crystal panel assembly 400 includes a display area DA and a peripheral area PA enclosing the display area DA. The display area DA is an area in which an image is actually displayed, and the peripheral area PA is an area in which the gate driver or the data driver described above is formed or a gate pad part 121P and a data pad part 171P including gate pads, data pads, or the like, which are parts connected to an external circuit, are positioned. The gate pads are wide parts positioned at distal ends of gate lines 121, and the data pads are wide parts positioned at distal ends of data lines 171.

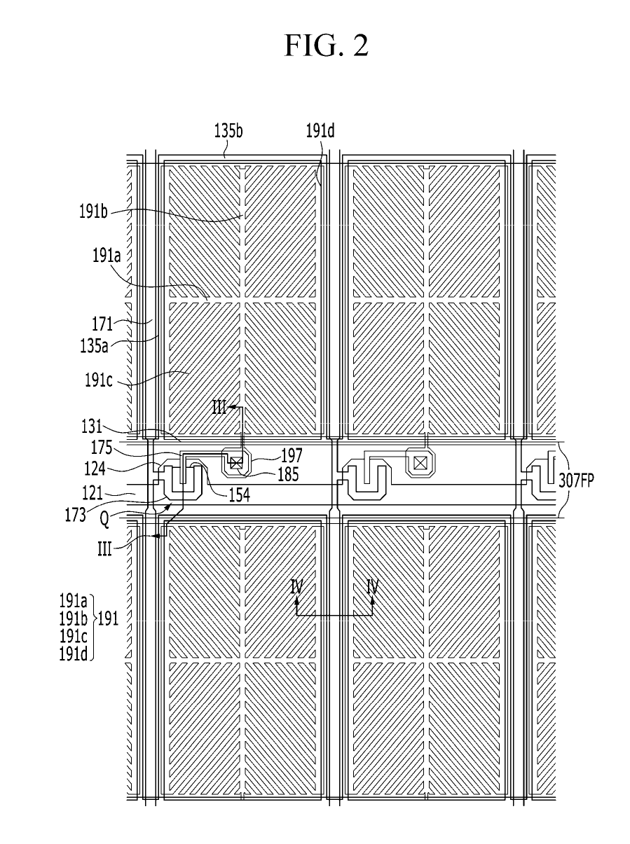

Hereinafter, components of the liquid crystal display in the display area DA will be described in detail with reference to FIGS. 2 to 4.

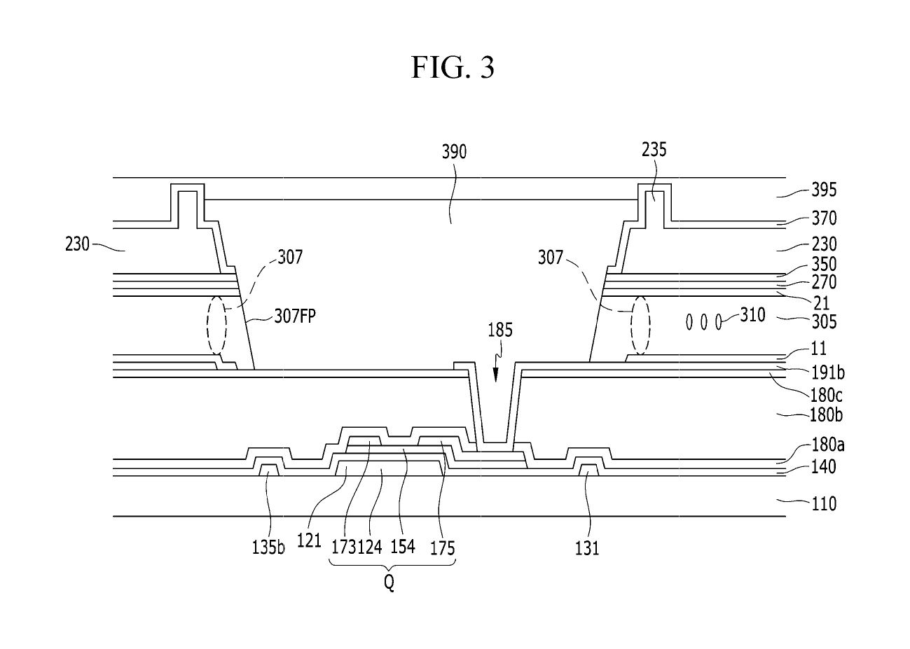

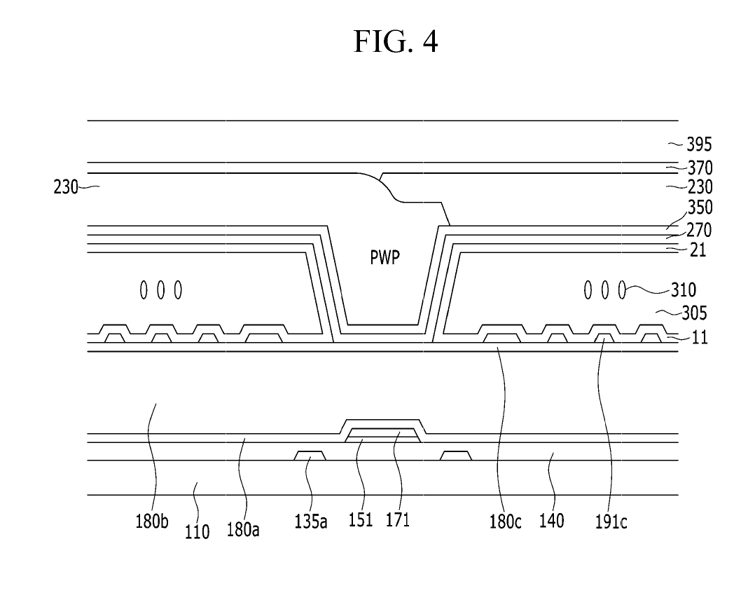

FIG. 2 is a plan view showing the liquid crystal display according to an exemplary embodiment of the present inventive concept. FIG. 3 is a cross-sectional view taken along line III-III of FIG. 2. FIG. 4 is a cross-sectional view taken along line IV-IV of FIG. 2.

FIG. 2 shows a 2×2 pixel area, which is a portion of a plurality of pixel areas, and these pixel areas may be repeatedly arranged in all directions in the liquid crystal display according to an exemplary embodiment of the present inventive concept.

Referring to FIGS. 2 to 4, gate lines 121 and sustain electrode lines 131 are formed on a substrate 110 made of transparent glass, plastic, or the like. The gate lines 121 include gate electrodes 124. The sustain electrode lines 131 are mainly extended in a horizontal direction and transfer a predetermined voltage such as a common voltage Vcom, or the like. The sustain electrode line 131 includes a pair of vertical parts 135a extended substantially vertically to the gate line 121 and a horizontal part 135b connecting ends of the pair of vertical parts 135a to each other. The vertical part 135a and the horizontal part 135b have a structure in which they enclose a pixel.

A gate insulating layer 140 is formed on the gate lines 121 and the sustain electrode lines 131. A semiconductor layer 151 disposed below data lines 171 and a semiconductor layer 154 disposed below source/drain electrodes and in a channel region of a thin film transistor Q is formed on the gate insulating layer 140.

A plurality of ohmic contact members (not shown) may be formed on the respective semiconductor layers 151 and 154 and between the data lines 171 and the source/drain electrodes.

Data conductors 171, 173, and 175 including a source electrode 173, the data line 171 connected to the source electrode 173, and a drain electrode 175 are formed on the respective semiconductor layers 151 and 154 and the gate insulating layer 140.

The gate electrode 124, the source electrode 173, and the drain electrode 175 form the thin film transistor Q together with the semiconductor layer 154, and a channel of the thin film transistor Q is formed in a portion of the semiconductor layer 154 between the source electrode 173 and the drain electrode 175.

A first interlayer insulating layer 180a is formed on portions of the semiconductor layer 154 that are not covered by the data conductors 171, 173, and 175 and the source electrode 173 and the drain electrode 175, but are exposed. The first interlayer insulating layer 180a may include an inorganic material such as a silicon nitride (SiNx) and a silicon oxide (SiOx).

A second interlayer insulating layer 180b and a third interlayer insulating layer 180c may be disposed on the first interlayer insulating layer 180a. The second interlayer insulating layer 180b may be made of an organic material, and the third interlayer insulating layer 180c may include an inorganic material such as a silicon nitride (SiNx) and a silicon oxide (SiOx). The second interlayer insulating layer 180b may be made of the organic material to decrease or remove a step. Unlike the present exemplary embodiment, one or two of the first interlayer insulating layer 180a, the second interlayer insulating layer 180b, and the third interlayer insulating layer 180c may be omitted.

A contact hole 185 may be formed to pass through the first interlayer insulating layer 180a, the second interlayer insulating layer 180b, and the third interlayer insulating layer 180c. The drain electrode 175 and the pixel electrode 191 disposed on the third interlayer insulating layer 180c may be electrically and physically connected to each other through the contact hole 185. Next, the pixel electrode 191 will be described in detail.

The pixel electrode 191 may be made of a transparent conductive material such as an ITO, an IZO, or the like.

The pixel electrode 191 generally has a rectangular shape, and includes a cross-shaped stem part including a horizontal stem part 191a and a vertical stem part 191b intersecting with the horizontal stem part 191a. In addition, the pixel electrode 191 is divided into four sub-regions by the horizontal stem part 191a and the vertical stem part 191b, wherein each of the sub-regions includes a plurality of fine branch parts 191c. In addition, in the present exemplary embodiment, the pixel electrode 191 may further include outer side stem parts 191d connecting the fine branch parts 191c to each other at left and right outer sides thereof. In the present exemplary embodiment, the outer side stem parts 191d may be positioned at the left and right outer sides of the pixel electrode 191 or be positioned so as to extend up to an upper portion or a lower portion of the pixel electrode 191.

The fine branch parts 191c of the pixel electrode 191 form an angle of approximately 40 degrees to approximately 45 degrees with respect to the gate line 121 or the horizontal stem part. In addition, the fine branch parts of two neighboring sub-regions may be orthogonal to each other. In addition, widths of the fine branch parts may become gradually wide or intervals between the fine branch parts 191c may be different from each other.

The pixel electrode 191 includes an extension part 197 connected thereto at a lower end of the vertical stem part 191b and having an area wider than that of the vertical stem part 191b, is physically and electrically connected to the drain electrode 175 through the contact hole 185 at the extension part 197, and receives a data voltage applied from the drain electrode 175.

The above-mentioned description for the thin film transistor Q and the pixel electrode 191 is only an example, and a structure of the thin film transistor and a design of the pixel electrode may be modified in order to improve side visibility.

A lower alignment layer 11 is disposed on the pixel electrode 191, and may be a vertical alignment layer. The lower alignment layer 11, which is a liquid crystal alignment layer made of polyamic acid, polysiloxane, polyimide, or the like, may include at least one of generally used materials. In addition, the lower alignment layer 11 may also be a photo-alignment layer.

An upper alignment layer 21 is disposed on a portion facing the lower alignment layer 11, and a micro-cavity is formed between the lower alignment layer 11 and the upper alignment layer 21. A liquid crystal material including liquid crystal molecules 310 is injected into the micro cavities 305, and the micro cavities 305 have inlets 307. The micro cavity 305 may be formed in a column direction of the pixel electrodes 191, in other words, in a vertical direction. In the present exemplary embodiment, the liquid crystal material including an alignment material forming the alignment layers 11 and 21 and the liquid crystal molecules 310 may be injected into the micro cavity 305 using capillary force. In the present exemplary embodiment, the lower alignment layer 11 and the upper alignment layer 21 are only distinguished from each other depending on their positions, and may be connected to each other, as shown in FIG. 4. The lower alignment layer 11 and the upper alignment layer 21 may be simultaneously formed.

The micro cavity is divided in the vertical direction by a plurality of liquid crystal inlets 307FP positioned at portions overlapping the gate line 121, such that a plurality of micro cavities 305 are formed. Here, the plurality of micro cavities 305 may extend along the column direction of the pixel electrodes 191, in other words, the vertical direction. In addition, the micro cavity 305 is divided in the horizontal direction by a partition wall part PWP to be described below, such that a plurality of micro cavities 305 are formed. Here, the plurality of micro cavities 305 may be formed in a row direction of the pixel electrodes 191, in other words, in the horizontal direction in which the gate lines 121 extend. Each of the plurality of micro cavities 305 may correspond to one or two or more pixel areas, which may correspond to areas in which an image is displayed.

A common electrode 270 and a lower insulating layer 350 are disposed on the upper alignment layer 21. The common electrode 270 receives a common voltage applied thereto and generates an electric field together with the pixel electrode 191 to which the data voltage is applied to determine a direction in which the liquid crystal molecules 310 disposed in the micro cavity 305 between the two electrodes are inclined. The common electrode 270 forms a capacitor together with the pixel electrode 191 to maintain the applied voltage even after the thin film transistor is turned off.

The lower insulting layer 350 may be made of a silicon nitride (SiNx) or a silicon oxide (SiOx).

Although the case in which the common electrode 270 is formed at an upper end portion of the micro cavity 305 has been described in the present exemplary embodiment, the common electrode 270 may be formed below the micro cavity 305 to drive liquid crystal in a horizontal electric field mode in another exemplary embodiment.

In the present exemplary embodiment, a roof layer 230 is disposed on the lower insulating layer 350. In the present exemplary embodiment, the roof layer 230 may be formed of a color filter.

As shown in FIG. 3, the roof layer 230 includes protrusion parts 235 positioned at one sides thereof adjacent to the plurality of liquid crystal inlets 307FP. The protrusion part 235 may protrude upwardly higher than a capping layer 390 described below. For example, the protrusion parts 235 have a convex portion in which the convex portion protrudes upwardly higher than the capping layer. That is, the roof layer 230 includes the protrusion parts 235 formed at one sides thereof adjacent to the plurality of liquid crystal inlets 307FP thereby confining the capping layer 390 including a light blocking material not to overflow onto the microcavity. To achieve this object, the protrusion part 235 may be protruded upwardly more than about 0.5 μm. The protrusion part 235 may be protruded upwardly from about 0.5 μm to about 3 μm.

As shown in FIG. 4, a roof layer 230 including color filter of one color among color filters neighboring to each other forms the partition wall part PWP. The partition wall part PWP is positioned between micro cavities 305 neighboring to each other in the horizontal direction. The partition wall part PWP is filled in a space between the micro cavities 305 neighboring to each other in the horizontal direction. Although the partition wall part PWP is formed in a structure in which it is completely filled in the space between the micro cavities 305 as shown in FIG. 4, the partition wall part PWP is not necessarily limited thereto, but may also be formed in a structure in which it is filled in a portion of the space. The partition wall part PWP may be formed in a region in which the data lines 171 extend.

The roof layer 230 including color filter neighboring to each other may be overlapped with each other above the partition wall part PWP. An interface on which the neighboring roof layers 230 including color filters meet each other may be positioned at a portion corresponding to the partition wall part PWP.

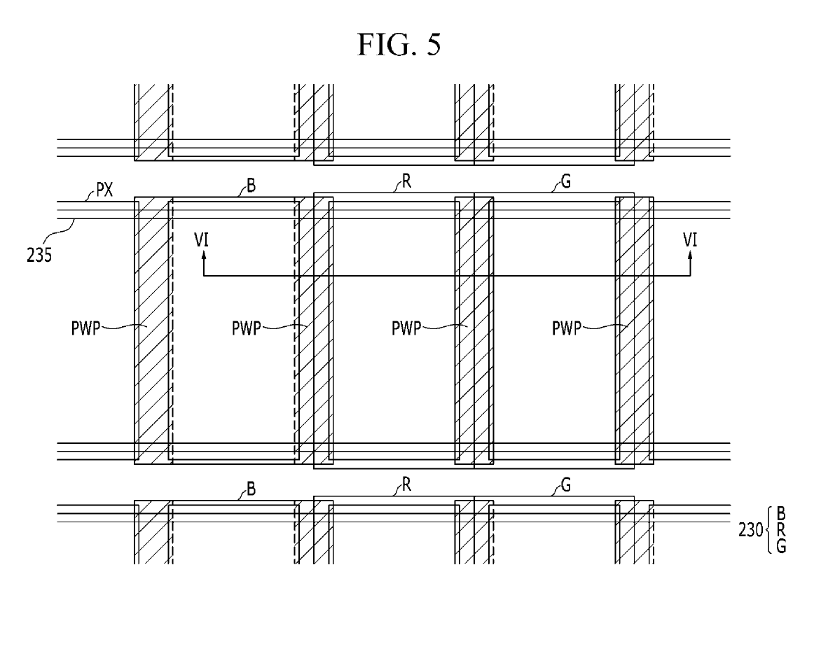

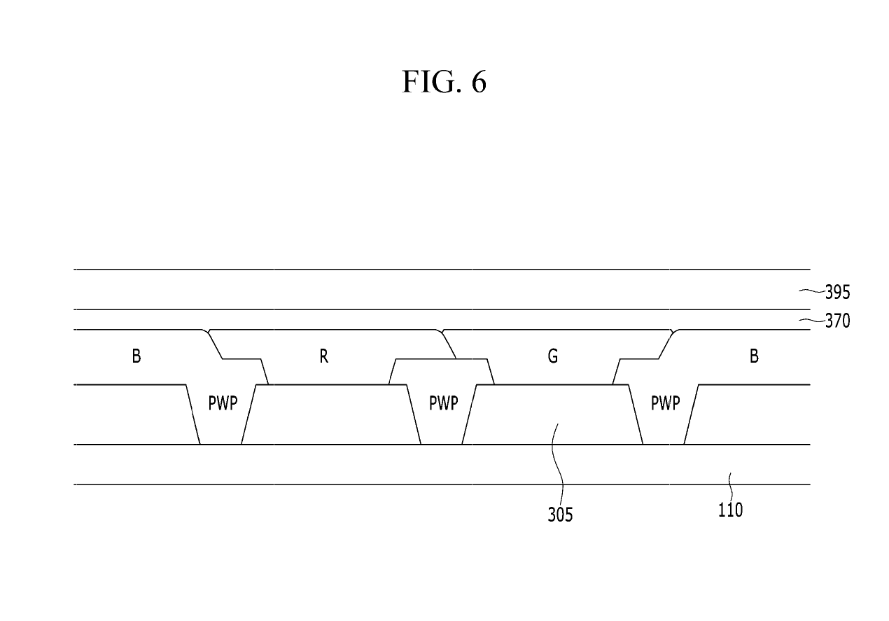

Next, the roof layer 230 including the color filter according to an exemplary embodiment of the present inventive concept will be described in detail with reference to FIGS. 5 and 6.

FIG. 5 is a plan view showing a color filter and a partition wall part in the liquid crystal display according to an exemplary embodiment of the present inventive concept. FIG. 6 is a cross-sectional view taken along line VI-VI of FIG. 5.

FIGS. 5 and 6 are schematic views for mainly describing the roof layer 230 including color filter and the partition wall part in the liquid crystal display according to an exemplary embodiment of the present inventive concept, and contents described with reference to FIGS. 2 to 4 may be applied to components between the substrate 110 and the micro cavities 305 as they are.

Referring to FIGS. 5 and 6, the roof layer 230 including color filter according to the present exemplary embodiment may include a first color filter, a second color filter, and a third color filter, wherein the first color filter may include a blue color filter B, the second color filter may include a red color filter R, and the third color filter may include a green color filter (G).

According to the present exemplary embodiment, the partition wall part PWP is formed by any one of the first color filter, the second color filter, and the third color filter. In an exemplary embodiment of the present inventive concept, the first color filter corresponding to the blue color filter B forms the partition wall part PWP. The blue color filter B may include a partition wall part PWP extended from a portion corresponding to the pixel area PX and a partition wall part PWP positioned between the red color filter R and the green color filter G. Here, the red color filter R and the green color filter G simultaneously cover opposed edge portions of adjacent partition wall parts PWP, and may be overlapped with each other on the partition wall part PWP.

The partition wall part PWP may also be formed by the red color filter R or the green color filter G instead of the blue color filter B. However, since the blue color filter B has a light blocking effect larger than that of the red color filter R or the green color G, when the partition wall part PWP is formed by the blue color filter B, light reflection by external light may be decreased. Further, since the blue color filter B serves to block the light and has excellent fluidity of a photo resist, which is a component of the color filter, it has a good taper angle. Therefore, when a undercut is generated in a shape of a distal end of the color filter forming the partition wall part PWP or the color filter is not vertically formed, but is formed in a state in which it lies down at an angle of approximately 45 degrees or more, the color filter applied onto the partition wall part PWP while covering a side wall of the partition wall part PWP may be formed well.

As shown in FIG. 5, the roof layer including color filter 230 may be formed in an island shape so as to correspond to the pixel area PX.

The present inventive concept is not limited to an exemplary embodiment described above. That is, the roof layer 230 including color filters 230 adjacent to the respective partition wall parts PWP may be extended to form the partition wall parts PWP.

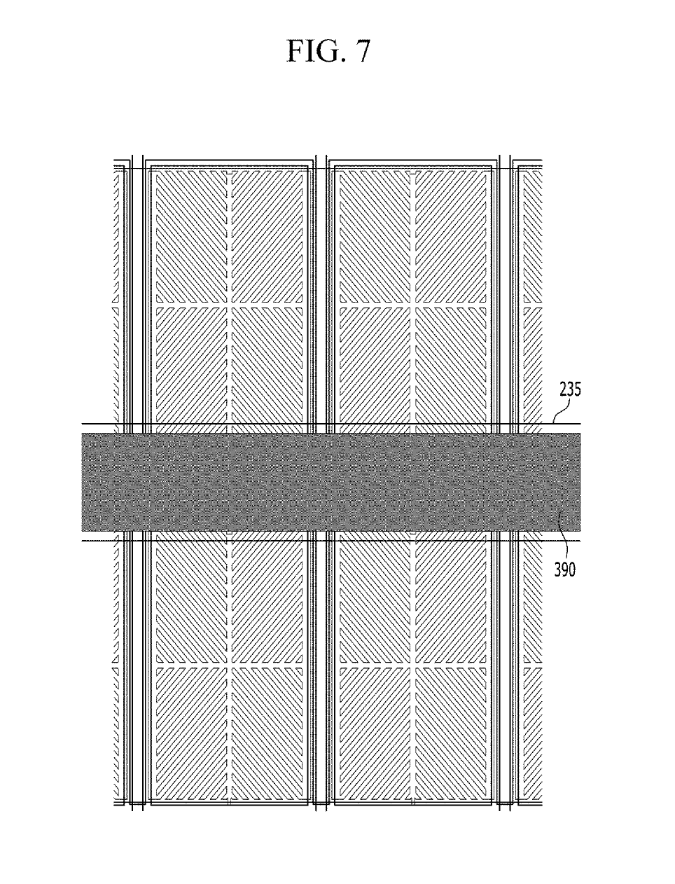

Again referring to FIGS. 3 and 4, an upper insulating layer 370 is disposed on the roof layer 230. The upper insulting layer 370 may be made of a silicon nitride (SiNx) or a silicon oxide (SiOx). As shown in FIG. 3, the upper insulating layer 370 may cover side surface portions of the color filters 230. FIG. 7 is a plan view showing a layout of a capping layer and a protrusion part in the liquid crystal display according to an exemplary embodiment of the present inventive concept.

Referring to FIGS. 3 and 7, the capping layer 390 is disposed in the liquid crystal inlets 307FP in the display area DA and covers the inlets 307 of the micro cavities 305 exposed by the liquid crystal inlets 307FP. The capping layer 390 may contact the liquid crystal material disposed in the micro cavity 305. In detail, the capping layer 390 may be disposed along the liquid crystal inlet 307FP, and may not be disposed above the micro cavity corresponding to the pixel area because the protrusion part 235 positioned adjacently to the liquid crystal inlet 307FP may prevent the capping layer 390 overflowing onto the micro cavity. That is, the protrusion part 235 according to an exemplary embodiment of the present inventive concept is disposed along the liquid crystal inlet 307FP at an outer side of the roof layer 230, thereby making it possible to prevent the capping layer 390 including the light blocking material suitable for inkjet processing from overflowing onto the micro cavity corresponding to the pixel area.

The capping layer 390 according to the present exemplary embodiment includes a water soluble polymer material and the light blocking material suitable for inkjet processing. In the present exemplary embodiment, the water soluble polymer material may be polyvinyl alcohol represented by the following Chemical Formula 1. In addition, the water soluble polymer material according to the present exemplary embodiment may include at least one of methoxypolyethylene glycol, polyethylene glycol, poly(ethylene glycol) diacrylate, polyethylene glycol dimethacrylate, and polyvinylpyrrolidone. In Chemical Formula, n indicates the number of repeated units, and may be a natural number.

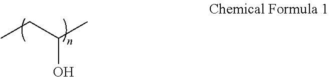

In the present exemplary embodiment, the light blocking material suitable for inkjet processing may include a water soluble black dye or a black pigment. The water soluble black dye may be dissolved in a capping material forming the capping layer 390, and the black pigment may be present in a form in which it is dispersed in the capping material.

The water soluble black dye according to the present exemplary embodiment may include at least one of 2-naphthalenesulfonic acid, trisodium 6-[(7-amino-1-hydroxy-3-sulphonato-2-naphthyl)azo]-3-[[4-[[4-amino-6 (or 7)-sulphonatonaphthyl]azo]phenyl]azo]-4-hydroxynaphthalene-2-sulphonate, trisodium 4-amino-3-[[4-[[4-[(2-amino-4-hydroxyphenyl)azo]phenyl]amino]-3-sulphonato phenyl]azo]-5-hydroxy-6-(phenylazo)naphthalene-2, 7-disulphonate, and disodium 4-amino-3, 6-bis[[4-[(2, 4-diaminophenyl) azo]phenyl]azo]-5-hydroxynaphthalene-2, 7-disulphonate 2, 7-naphthalenedisulfonic acid.

In the present exemplary embodiment, since the capping layer 390 includes the water soluble polymer material, even though the capping layer contacts the liquid crystal material, which is hydrophobic, the liquid crystal material is not polluted. In addition, since the capping layer 390 includes the light blocking material suitable for inkjet processing it may serve as a black matrix for blocking light leakage. Therefore, a separate process for forming the black matrix serving as a light blocking member may be omitted.

In addition, as compared with the case in which the capping layer 390 is formed by a photo process, the capping layer 390 according to an exemplary embodiment of the present inventive concept includes the light blocking material suitable for inkjet, thereby making it possible to simplify the photo process and a mask process to an inkjet process.

An overcoat 395 formed as an inorganic layer or an organic layer may be disposed on the capping layer 390. The overcoat 395 serves to protect the liquid crystal molecules 310 injected into the micro cavity 305 from external impact and planarize a top surface of the LCD device. In addition, the overcoat 395 may also serve to block external moisture and oxygen.

In the present exemplary embodiment, as shown in FIG. 4, the partition wall part PWP is formed by the roof layer 230 including color filter of one color between the micro cavities 305 neighboring to each other in the horizontal direction. The partition wall part PWP forms a partition wall, thereby making it possible to partition or define the micro cavities 305. In the present exemplary embodiment, since a partition wall structure such as the partition wall part PWP is present between the micro cavities 305, even though the substrate 110 is bent, stress is less generated, and a change degree of a cell gap may be decreased.

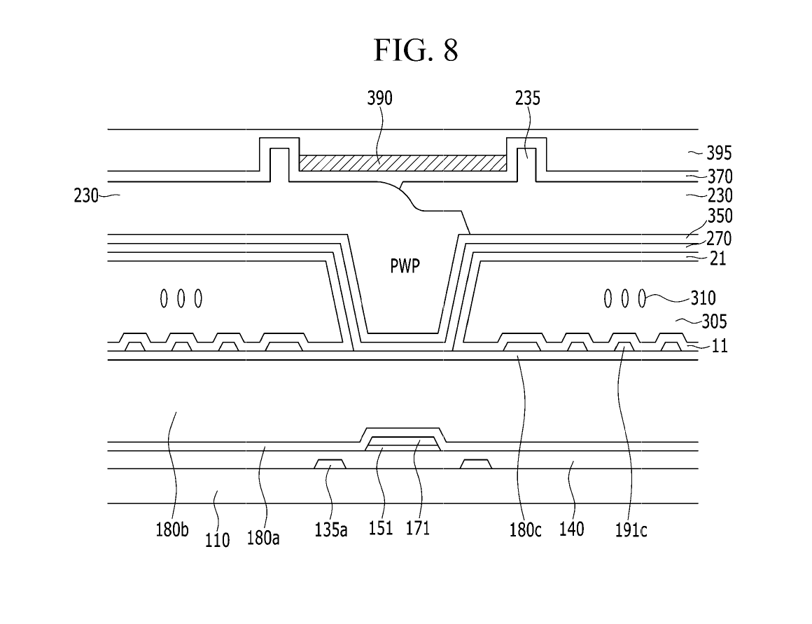

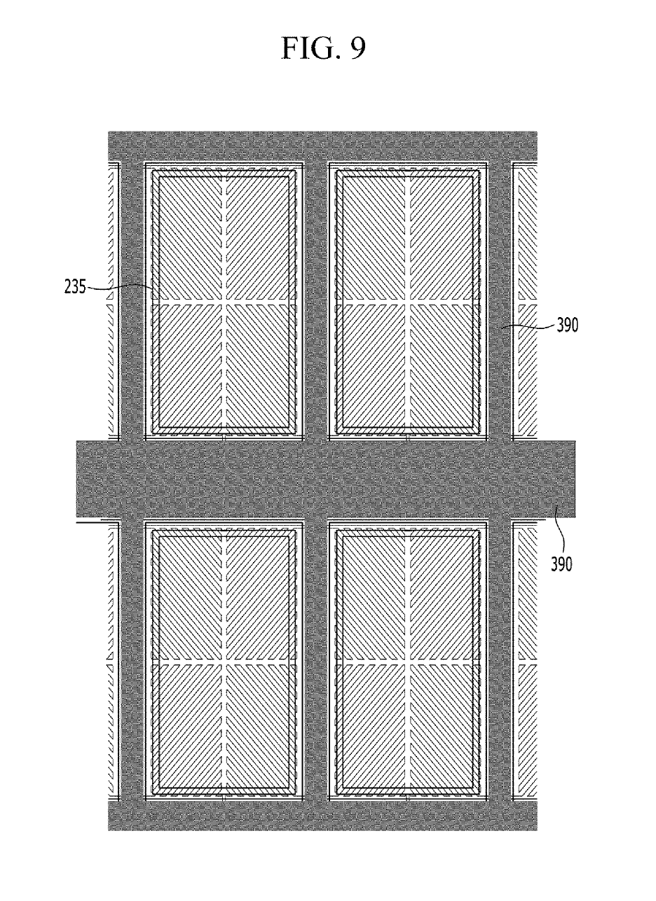

FIG. 8 is a cross-sectional view showing a liquid crystal display modified from an exemplary embodiment of FIG. 4. FIG. 9 is a plan view showing a layout of a capping layer and a protrusion part in the liquid crystal display according to an exemplary embodiment of the present inventive concept of FIG. 8.

Referring to FIGS. 8 and 9, the liquid crystal display according to the present exemplary embodiment is substantially the same as the liquid crystal display according to an exemplary embodiment of FIG. 4 except that the capping layer 390 is not only formed along the liquid crystal inlet 307FP, but is also disposed on the upper insulating layer 370 in the direction in which the data lines 171 extend. The capping layer 390 described herein may include a first light blocking member disposed along the liquid crystal inlet 307FP and a second light blocking member disposed in the direction in which the data lines 171 extend, wherein the first light blocking member and the second light blocking member may be formed by the same process using the same material. As shown in FIG. 9, the first light blocking member and the second light blocking member may be formed in a matrix form.

Here, the roof layer 230 may include protrusion parts 235 formed at one sides thereof adjacent to the first light blocking member and the second light blocking member. The protrusion part may be protruded upwardly higher than the first light blocking member and the second light blocking member. To achieve this object, the protrusion part 235 may be protruded upwardly more than about 0.5 μm. The protrusion part 235 may be protruded upwardly from about 0.5 μm to about 3 μm.

In detail, the capping layer 390 including the first light blocking member and the second light blocking member is formed in the direction in which the liquid crystal inlet 307FP and the data line 171 extend, and may not be formed above the micro cavity corresponding to the pixel area by forming the protrusion parts 235 positioned adjacently to the liquid crystal inlet 307FP and the data line 171. That is, the protrusion parts 235 according to an exemplary embodiment of the present inventive concept are positioned along the first light blocking member and the second light blocking member at an outer side of the roof layer 230, thereby making it possible to prevent the capping layer 390 from overflowing onto the micro cavity corresponding to the pixel area.

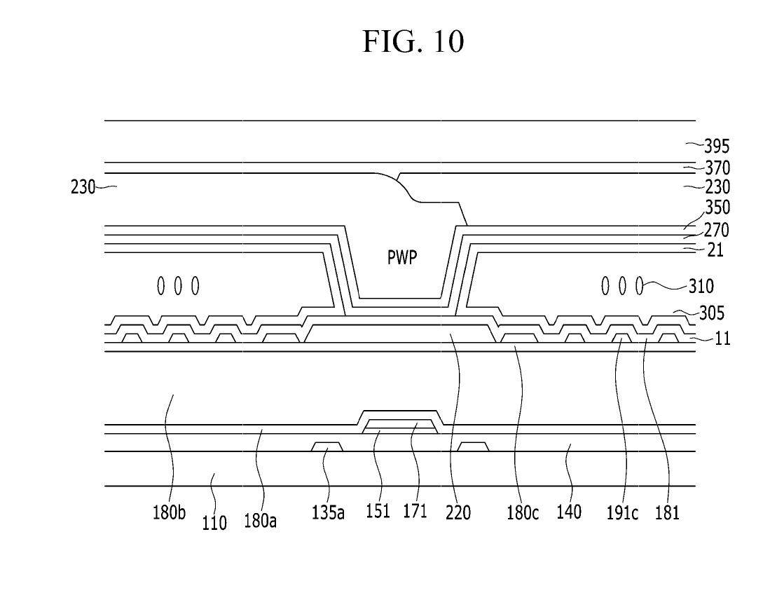

FIG. 10 is a cross-sectional view showing a liquid crystal display modified from an exemplary embodiment of FIG. 4.

Referring to FIG. 10, the liquid crystal display according to the present exemplary embodiment is substantially the same as the liquid crystal display according to an exemplary embodiment of FIG. 4 except that a light blocking member 220 is formed in the direction in which the data lines 171 extend. The light blocking member 220 is positioned on the third interlayer insulating layer 180c or the pixel electrode 191. The light blocking member 220 described herein may have a matrix form together with the capping layer 390 extending in the direction in which the gate lines 121 extend, when viewed in a plane. The light blocking member 220 may include a material different from that of the capping layer 390. The light blocking member 220 may include an organic material unlike the capping layer 390.

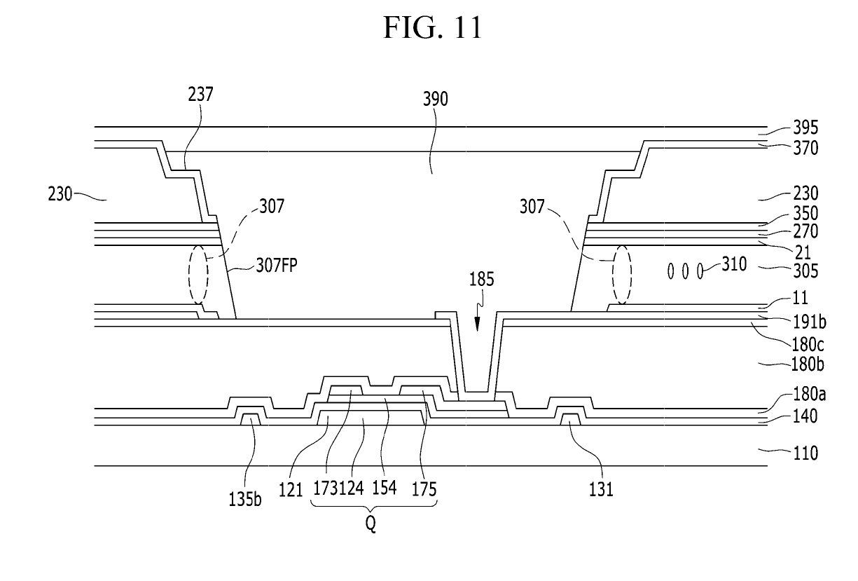

FIG. 11 is a cross-sectional view showing a liquid crystal display modified from an exemplary embodiment of FIG. 3. The liquid crystal display according the present exemplary embodiment is substantially the same as the liquid crystal display described with reference to FIG. 3 except that a shape of one side of the roof layer 230 is changed.

The roof layer 230 includes concave parts 237 formed at one sides thereof adjacent to the liquid crystal inlets 307FP and having a form in which they have surfaces recessed more concavely as compared with the roof layer 230. Here, one side surface of the concave part 237 has a step, thereby making it possible to prevent the capping layer 390 from overflowing onto the roof layer 230.

That is, the capping layer 390 covering the liquid crystal inlet 307FP may not be formed above the micro cavity corresponding to the pixel area by the concave part 237 of the roof layer 230.

In addition, a surface of the roof layer 230 is formed so as to have hydrophobicity, thereby making it possible to prevent the capping layer 390 having hydrophilicity from flowing onto the micro cavity corresponding to the pixel area.

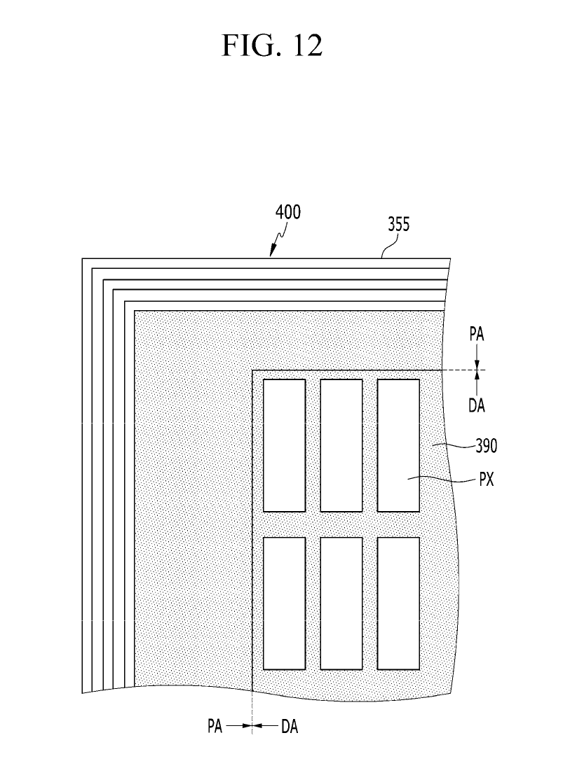

FIGS. 12 to 14 are views showing a liquid crystal display according to another exemplary embodiment of the present inventive concept.

Referring to FIGS. 12 to 14, the liquid crystal display according to another exemplary embodiment of the present inventive concept may further include a plurality of dummy dams 355 in order to prevent the capping layer 390 from flowing to an outer side of the liquid crystal panel assembly 400 or the peripheral area PA and in order to prevent external light from being incident. The dummy dams 355 protrude upwardly higher than the capping layer 390. The dummy dam 355 may be protruded upwardly more than about ???μm. The protrusion part 235 may be protruded upwardly from about ??? μm to about ??? μm.

As shown in FIG. 12, the plurality of dummy dams 355 are formed at the outer side of the liquid crystal panel assembly 400, thereby making it possible to prevent the external light from being incident to the liquid crystal panel assembly 400.

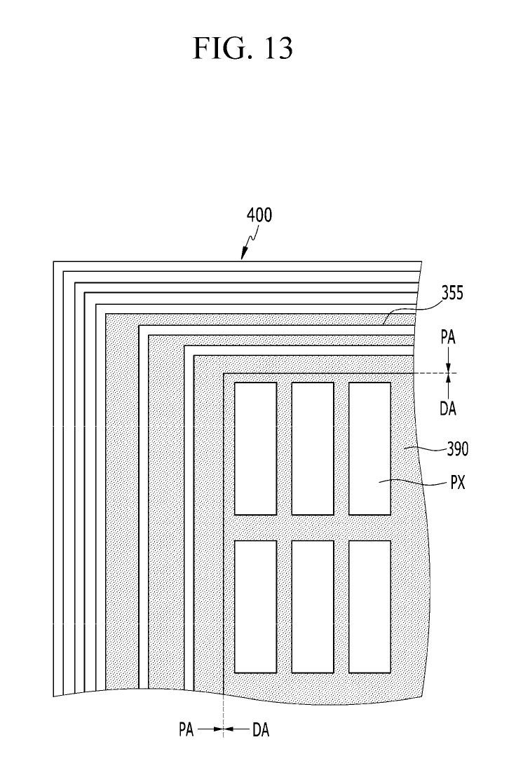

As shown in FIG. 13, the plurality of dummy dams 355 are also formed in the peripheral area PA of the liquid crystal panel assembly 400, thereby making it possible to prevent the capping layer 390 from flowing to the peripheral area PA.

The plurality of dummy dams 355 may be formed at predetermined intervals while enclosing the display area DA.

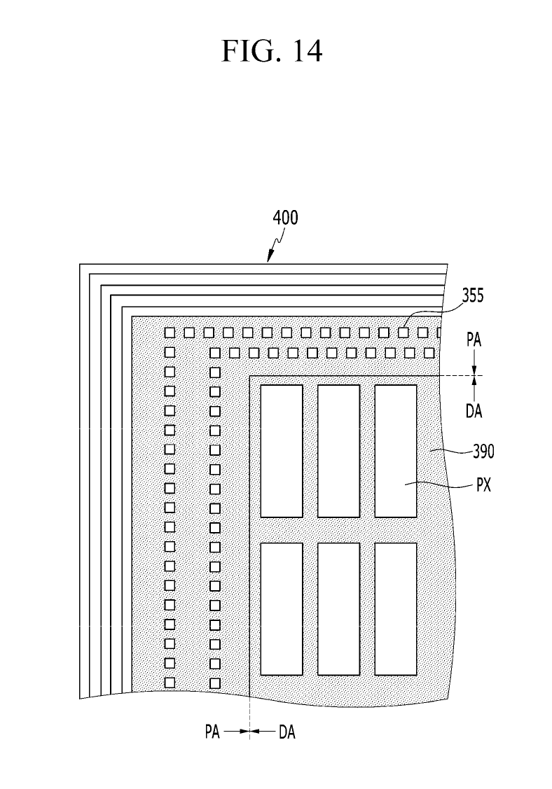

Here, as shown in FIG. 14, the plurality of dummy dams 355 positioned in the peripheral area PA of the liquid crystal panel assembly 400 may have various forms such as a line form, a dot form, and the like.

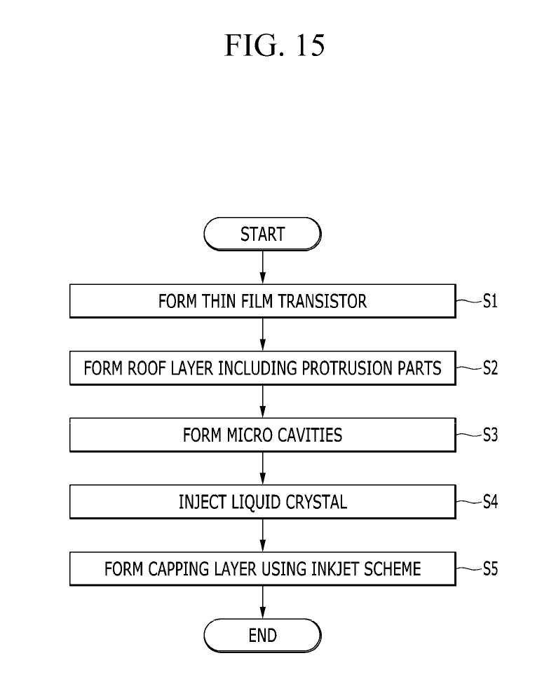

FIG. 15 is a flow chart showing a method for manufacturing a liquid crystal display according to an exemplary embodiment of the present inventive concept.

Referring to FIG. 15, the method for manufacturing a liquid crystal display according to an exemplary embodiment of the present inventive concept includes forming the thin film transistor on the substrate (S1).

The thin film transistor serves as a switching element in the present exemplary embodiment, and may control, input and output a signal in order to display an image.

Although one thin film transistor Q is formed in a unit pixel, as shown in FIG. 2, to control, input, and output a signal in the present exemplary embodiment, a structure of the thin film transistor may be modified.

Again referring to FIGS. 2 to 4, the first interlayer insulating layer 180a, the second interlayer insulating layer 180b, and the third interlayer insulating layer 180c are formed on the thin film transistor Q, and the contact hole 185 pass through the first interlayer insulating layer 180a, the second interlayer insulating layer 180b, and the third interlayer insulating layer 180c is formed. Then, the pixel electrode 191 is formed on the third interlayer insulating layer 180c, wherein the pixel electrode 191 is electrically and physically to the drain electrode 175 of the thin film transistor Q through the contact hole 185.

Next, a sacrificial layer 300 is formed on the pixel electrode 191. Here, an open part (not shown) is formed in a direction that is in parallel with the data line 171 in the sacrificial layer 300. The color filter 230 may be filled in the open part in a subsequent process to form the partition wall part PWP. The sacrificial layer 300 may be made of a photo resist material or an organic material except for the photo resist material. The pixel electrode 191 may be made of a transparent conductor such as an ITO or an IZO.

Then, the method for manufacturing a liquid crystal display according to an exemplary embodiment of the present inventive concept includes forming the roof layer including the protrusion parts 235 (S2).

A method for forming the roof layer 230 will be described again with reference to FIGS. 2 to 4. The common electrode 270 and the lower insulating layer 350 are sequentially formed on the sacrificial layer. The common electrode 270 may be made of a transparent conductor such as an ITO or an IZO, and the lower insulating layer 350 may be made of a silicon nitride (SiNx) or a silicon oxide (SiO2).

The roof layer 230 is formed on the lower insulating layer 350. The roof layer 230 according to the present exemplary embodiment may be formed of the color filter. Here, the roof layer 230 may include the protrusion parts 235 formed at one sides thereof adjacent to the liquid crystal inlet 307FP and having a form in which they have relatively further protruding surfaces.

The roof layer 230 and the protrusion parts 235 may be formed at a time by patterning the same material, for example, a color filter material using a half tone mask or a slit mask. In addition, the roof layer 230 formed of the color filter may be removed in portions in which the liquid crystal inlets 307FP are to be formed by a patterning process or an exposure/development process.

The upper insulating layer 370 is formed on the roof layer 230. The upper insulting layer 370 may be made of a silicon nitride (SiNx) or a silicon oxide (SiO2).

Then, the method for manufacturing a liquid crystal display according to an exemplary embodiment of the present inventive concept includes forming the micro cavity (S3).

Again referring to FIGS. 2 to 4, the upper insulating layer 370, the lower insulating layer 350, and the common electrode 270 positioned so as to correspond to the liquid crystal inlets 307FP are sequentially patterned to expose the sacrificial layer, and the sacrificial layer is removed by oxygen (O2) ashing, a wet etching method, or the like, through the liquid crystal inlets 307FP. In this case, the micro cavities 305 having the inlets 307 are formed. The sacrificial layer is removed, such that the micro cavities 305 are in an empty space state.

The alignment material is injected through the inlets 307 to form the alignment layers 11 and 21 on the pixel electrode 191 and the common electrode 270.

Next, the liquid crystal material including the liquid crystal molecules 310 is injected into the micro cavities 305 through the inlets 307 using an inkjet scheme, or the like (S4).

Next, when the liquid crystal material is injected, the liquid crystal material may be exposed to the outside by the liquid crystal inlets 307FP, the capping layer 390 is formed using an inkjet scheme so as to cover the liquid crystal inlets 307FP (S5). As an example, the light blocking material suitable for inkjet is discharged from a printing head of an inkjet printer (not shown) to the liquid crystal inlet 307FP. The light blocking material suitable for inkjet may include the water soluble black dye or the black pigment, as described above. Here, a phenomenon that the light blocking material suitable for inkjet flows onto the micro cavities 305 corresponding to the pixel areas is prevented by the protrusion parts 235, thereby making it possible to form the capping layer opened in a region corresponding to the micro cavity.

The capping layer 390 is formed using the inkjet scheme in the liquid crystal display according to an exemplary embodiment of the present inventive concept, thereby making it possible to simplify a manufacturing process as compared with a liquid crystal display according to comparative example in which a photo process is used in order to cover the liquid crystal inlets 307FP and open the micro cavities 305 corresponding to the pixel areas.

While this inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

What is claimed is:

1. A liquid crystal display comprising:
a substrate including a display area and a peripheral area;
a plurality of thin film transistors disposed on the substrate in the display area;
a plurality of pixel electrodes disposed on the plurality of thin film transistors and connected to the plurality of thin film transistor, respectively;
a plurality of roof layers disposed on the plurality of pixel electrodes so as to face the plurality of pixel electrodes;
a plurality of liquid crystal layers disposed in a plurality of micro cavities formed between the plurality of pixel electrodes and the roof layer; and
a capping layer covering liquid crystal inlets formed between the plurality of micro cavities and including a light blocking material suitable for inkjet processing,
wherein the plurality of roof layers includes protrusion parts or concave parts disposed at one side of the plurality of roof layers adjacent to the capping layer.

2. The liquid crystal display of claim 1, wherein:
the capping layer is disposed along the liquid crystal inlets.

3. The liquid crystal display of claim 2, wherein: each of the protrusion parts has a convex portion in which the convex portion protrudes upwardly higher than the capping layer.

4. The liquid crystal display of claim 2, wherein:
the capping layer is protruded upwardly from about 0.5 μm to about 3 μm.

5. The liquid crystal display of claim 1, wherein:
the capping layer includes a first light blocking member disposed along the liquid crystal inlets and a second light blocking member disposed along data lines and intersecting with the first light blocking member, and
the first light blocking member and the second light blocking member include the same material.

6. The liquid crystal display of claim 5, wherein:
the protrusion parts are formed at sides of the plurality of roof layers adjacent to the first light blocking member and the second light blocking member, and have a convex portion in which the convex portion protrudes upwardly higher than the first light blocking member and the second light blocking member.

7. The liquid crystal display of claim 1, wherein:
the concave parts have a form in which the concave parts are relatively further recessed concavely as compared with the roof layer.

8. The liquid crystal display of claim 7, wherein:
the capping layer has hydrophilicity, and
a surface of the roof layer has hydrophobicity.

9. The liquid crystal display of claim 1, further comprising:
a plurality of dummy dams formed in the peripheral area and enclosing the display area, the dummy dams protruding upwardly higher than the capping layer.

10. The liquid crystal display of claim 9, further comprising:
a plurality of dummy dams formed in at an outer side of the peripheral area and enclosing the peripheral area.

11. The liquid crystal display of claim 9, wherein:
the plurality of dummy dams have a stripe shape or a dot shape.

12. The liquid crystal display of claim 1, wherein:
the light blocking material suitable for inkjet processing includes a water soluble black dye or a black pigment.

13. The liquid crystal display of claim 12, wherein:
the water soluble black dye includes at least one of 2-naphthalenesulfonic acid, trisodium 6-[(7-amino-1-hydroxy-3-sulphonato-2-naphthyl)azo]-3-[[4-[[4-amino-6 (or 7)-sulphonatonaphthyl]azo]phenyl]azo]-4-hydroxynaphthalene-2-sulphonate, trisodium 4-amino-3-[[4-[[4-[(2-amino-4-hydroxyphenyl)azo]phenyl]amino]-3-sulphonato phenyl]azo]-5-hydroxy-6-(phenylazo)naphthalene-2, 7-disulphonate, and disodium 4-amino-3, 6-bis[[4-[(2, 4-diaminophenyl) azo]phenyl]azo]-5-hydroxynaphthalene-2, 7-disulphonate 2, 7-naphthalenedisulfonic acid.

14. A method for manufacturing a liquid crystal display, comprising:
forming a plurality of thin film transistors on a substrate including a display area and a peripheral area;
forming a plurality of pixel electrodes on the plurality of thin film transistors in the display area;
forming a plurality of sacrificial layers on the plurality of pixel electrodes;
forming a plurality of roof layers on the plurality of sacrificial layers, the plurality of roof layers including protrusion parts;
forming micro cavities between which liquid crystal inlets are formed by removing the sacrificial layer;
injecting a liquid crystal material into the micro cavities through the liquid crystal inlets; and
forming a capping layer in the display area and the peripheral area using an inkjet processing so as to cover the liquid crystal inlets.

15. The method for manufacturing a liquid crystal display of claim 14, wherein:
the capping layer is disposed along the liquid crystal inlets.

16. The method for manufacturing a liquid crystal display of claim 15, wherein:
the protrusion parts are formed at one side of the roof layers adjacent to the liquid crystal inlets, the protrusion part protruding upwardly higher than the capping layer.

17. The method for manufacturing a liquid crystal display of claim 16, wherein:
the capping layer is protruded upwardly from about 0.5 μm to about 3 μm.

18. The method for manufacturing a liquid crystal display of claim 16, wherein:
the roof layer and the protrusion parts are made of the same material.

19. The method for manufacturing a liquid crystal display of claim 14, wherein:
the capping layer includes a light blocking material suitable for inkjet processing.

20. The method for manufacturing a liquid crystal display of claim 19, wherein:
the light blocking material suitable for inkjet processing includes a water soluble black dye or a black pigment.
